(19) United States
(12) Patent Application Publication
(10) Pub. No.: US 2013/0026462 A1
(43) Pub. Date: Jan. 31, 2013

(54) METHOD FOR MANUFACTURING THIN FILM TRANSISTOR AND THIN FILM TRANSISTOR MANUFACTURED BY THE SAME, AND ACTIVE MATRIX SUBSTRATE

(71) Applicants: Michiko Takei, Osaka-shi (JP); Yoshimasa Chikama, Osaka-shi (JP); Tsuyoshi Inoue, Osaka-shi (JP); Masahiko Suzuki, Osaka-shi (JP); Okifumi Nakagawa, Osaka-shi (JP); Yoshifumi Ohta, Osaka-shi (JP); Yoshiyuki Harumoto, Osaka-shi (JP); Hinae Mizuno, Yamato-shi (JP)

(72) Inventors: Michiko Takei, Osaka-shi (JP); Yuuji Mizuno, Osaka-shi (JP); Yoshimasa Chikama, Osaka-shi (JP); Tsuyoshi Inoue, Osaka-shi (JP); Masahiko Suzuki, Osaka-shi (JP); Okifumi Nakagawa, Osaka-shi (JP); Yoshifumi Ohta, Osaka-shi (JP); Yoshiyuki Harumoto, Osaka-shi (JP)

(73) Assignee: Sharp Kabushiki Kaisha, Osaka-shi, Osaka (JP)

(21) Appl. No.: 13/581,094

(22) PCT Filed: Feb. 14, 2011
(86) PCT No.: PCT/JP2011/000804

§ 371 Date: Sep. 12, 2012

(30) Foreign Application Priority Data
Mar. 4, 2010 (JP) 2010-047849

(51) Int. Cl. H01L 29/786; H01L 21/336

(52) U.S. Cl. 257/43; 438/104; 438/158; 257/E21.409; 257/E29.273

(57) ABSTRACT

A method for manufacturing a thin film transistor includes the step of forming a gate electrode (11aa) on an insulating substrate, the step of forming a gate insulating layer (12) to cover the gate electrode (11aa), and thereafter, forming an oxide semiconductor layer (13a) on the gate insulating layer (12), the step of forming a source electrode (16aa) and a drain electrode (16b) on the oxide semiconductor layer (13a) by dry etching, with a channel region (C) of the oxide semiconductor layer being exposed, and the step of supplying oxygen radicals to a channel region of the oxide semiconductor layer.

### TECHNICAL FIELD

The present invention relates to methods for manufacturing thin film transistors, and more particularly, to methods for manufacturing thin film transistors including a semiconductor layer of an oxide semiconductor and the thin film transistors manufactured by the methods, and active matrix substrates.

### BACKGROUND ART

An active matrix substrate includes thin film transistors (hereinafter also referred to as “TFTs”) as switching elements, one for each pixel, which is the smallest unit of an image.

For example, a typical TFT includes a gate electrode provided on an insulating substrate, a gate insulating layer covering the gate electrode, an island-like semiconductor layer provided on the gate insulating layer over the gate electrode, and a source electrode and a drain electrode provided on the semiconductor layer, facing each other.

Here, in a TFT including amorphous silicon, the semiconductor layer includes an intrinsic amorphous silicon layer having a channel region and an N⁺ amorphous silicon layer provided on the intrinsic amorphous silicon layer with the channel region being exposed through the N⁺ amorphous silicon layer. As the TFT including amorphous silicon, an etch stopper type TFT has been put into practice in which a channel protection layer is provided on the intrinsic amorphous silicon layer in order to reduce the thickness of the intrinsic amorphous silicon layer.

In recent years, for active matrix substrates, a TFT including a semiconductor layer of an oxide semiconductor (hereinafter also referred to as an “oxide semiconductor layer”) has been proposed as a switching element for each pixel, which is the smallest unit of an image, instead of conventional thin film transistors including a semiconductor layer of amorphous silicon.

For example, PATENT DOCUMENT 1 describes an active matrix image display device in which the active layer of a field effect transistor for driving a light control element is formed of amorphous oxide having a predetermined electron carrier concentration.

FIG. 11 is a cross-sectional view of a conventional active matrix substrate 120 including a TFT 105 including an oxide semiconductor layer.

As shown in FIG. 11, the active matrix substrate 120 includes an insulating substrate 110, the TFT 105 provided on the insulating substrate 110, a protection insulating layer 115 covering the TFT 105, an interlayer insulating layer 116 covering the protection insulating layer 115, and a pixel electrode 117 provided on the interlayer insulating layer 116 and connected to the TFT 105. Here, as shown in FIG. 17, the TFT 105 includes a gate electrode 111 provided on the insulating substrate 110, a gate insulating layer 112 covering the gate electrode 111, an island-like oxide semiconductor layer 113 provided on the gate insulating layer 112 over the gate electrode 111, and a source electrode 114a and a drain electrode 114b on the oxide semiconductor layer 113, overlapping the gate electrode 111 and facing each other.

When the active matrix substrate 120 including the semiconductor layer of the oxide semiconductor 113 (including the TFT) is manufactured, the source electrode 114a and the drain electrode 114b are typically formed by patterning using dry etching (see, for example, NON-PATENT DOCUMENT 1).

### CITATION LIST

### Patent Document

PATENT DOCUMENT 1: Japanese Patent Publication No. 2006-165528

### Non-Patent Document

NON-PATENT DOCUMENT 1: Ikuhiro Ukai, “All About Thin Film Transistor Technology,” Kogakuchosakai, 2007, p. 145

### SUMMARY OF THE INVENTION

### Technical Problem

Here, as described above, the source electrode 114a and the drain electrode 114b are formed by patterning using dry etching. In this case, the channel region C of the oxide semiconductor layer 113 exposed between the source electrode 114a and the drain electrode 114b is likely to be damaged by dry etching, resulting in a degradation in characteristics of the TFT 105.

More specifically, the damage by dry etching causes a lack of oxygen, which in turn causes a change in composition, in the channel region C of the oxide semiconductor 113. The composition change is accompanied by occurrence of a defect, which in turn leads to a degradation in characteristics of the TFT 105, such as an increase in off-current, a decrease in electron mobility, hysteresis in transfer characteristics (the magnitude of a drain current caused by a change in gate voltage), etc.

The present invention has been made in view of the above problem. It is an object of the present invention to provide a method for manufacturing a thin film transistor having satisfactory TFT characteristics while reducing or preventing damage to the oxide semiconductor layer, and the thin film transistor manufactured by the method, and an active matrix substrate.

### Solution to the Problem

To achieve the object, a method according to the present invention is a method for manufacturing a thin film transistor including a gate electrode provided on an insulating substrate, a gate insulating layer covering the gate electrode, an oxide semiconductor layer having a channel region provided on the gate insulating layer over the gate electrode, and a source electrode and a drain electrode provided on the oxide semiconductor layer, overlapping the gate electrode and facing each other with the channel region being interposed the source and drain electrodes. The method includes a gate electrode forming step of forming the gate electrode on the insulating substrate, a semiconductor layer forming step of forming the gate insulating layer to cover the gate electrode formed in the gate electrode forming step, and thereafter, forming the oxide semiconductor layer on the gate insulating layer, a source/drain forming step of forming the source and drain electrodes by dry etching on the oxide semiconductor layer formed in the semiconductor layer forming step, with the channel region of the oxide semiconductor layer being exposed, and a surface treatment step of performing a surface treatment on the channel region of the oxide semiconductor layer by supplying oxygen radicals thereto.

With this configuration, after the source and drain electrodes are formed on the oxide semiconductor layer by dry etching, a surface treatment is performed on the channel region of the oxide semiconductor layer by supplying oxygen radicals thereto. Therefore, oxygen radicals are supplied to the channel region of the oxide semiconductor layer in which a change in the composition has occurred due to a lack of oxygen caused by the dry etching, whereby the lack of oxygen in the oxide semiconductor layer can be improved (terminated). As a result, in the thin film transistor, damage to the oxide semiconductor layer can be reduced or suppressed, and in addition, disadvantages which occur due to the composition change caused by the lack of oxygen, such as an increase in off-current, a decrease in electron mobility, occurrence of hysteresis in transfer characteristics, etc., can be reduced or prevented. Therefore, satisfactory thin film transistor characteristics can be obtained.

In the thin film transistor manufacturing method of the present invention, in the surface treatment step, the oxygen radicals produced by an atmospheric-pressure plasma treatment may be supplied.

With this method, the atmospheric-pressure plasma treatment is used to produce the oxygen radicals, and therefore, the oxygen radicals can be produced by a simple technique. Also, unlike the vacuum plasma treatment, a line gas, such as nitrogen gas etc., can be used, and therefore, inert gas is not required, resulting in a reduction in cost compared to the vacuum plasma treatment.

In the thin film transistor manufacturing method of the present invention, the oxygen radicals may be produced by decomposing oxygen gas by plasma.

With this method, the oxygen radicals can be produced by a simple technique.

In the thin film transistor manufacturing method of the present invention, the oxygen radicals may be produced by a plasma generator facing the oxide semiconductor layer.

With this method, unlike commonly used vacuum plasma apparatuses, in which a target to be treated is provided between electrodes, the plasma generator is positioned to face the oxide semiconductor layer which is a target to be treated, and therefore, only the oxygen radicals can be supplied to the channel region of the oxide semiconductor layer without damage to the oxide semiconductor layer which is caused by the plasma treatment. Therefore, the lack of oxygen in the oxide semiconductor layer can be improved without damage caused by the plasma treatment.

In the thin film transistor manufacturing method of the present invention, the oxygen radicals may be supplied to the channel region while the oxide semiconductor layer is being transported.

With this method, the oxygen radicals are supplied to the channel region while the oxide semiconductor layer is being transported. Therefore, the oxygen radicals can be efficiently supplied to the entire channel region of the oxide semiconductor layer. As a result, the lack of oxygen in the oxide semiconductor layer can be more effectively improved.

In the thin film transistor manufacturing method of the present invention, the oxide semiconductor layer may be formed of a metal oxide containing at least one selected from the group consisting of indium (In), gallium (Ga), aluminum (Al), silicon (Si), copper (Cu), and zinc (Zn).

With this method, the oxide semiconductor layer of these materials has a high mobility even if it is amorphous, and therefore, the on-resistance of the switching element can be increased.

In the thin film transistor manufacturing method of the present invention, the oxide semiconductor layer may be formed of an In—Ga—Zn—O metal oxide.

With this method, the thin film transistor can have satisfactory characteristics, i.e., high mobility and low off-current.

Another method according to the present invention is a method for manufacturing a thin film transistor including a gate electrode provided on an insulating substrate, a gate insulating layer covering the gate electrode, an oxide semiconductor layer having a channel region provided on the gate insulating layer over the gate electrode, and a source electrode and a drain electrode provided on the oxide semiconductor layer, overlapping the gate electrode and facing each other with the channel region being interposed the source and drain electrodes. The method includes a gate electrode forming step of forming the gate electrode on the insulating substrate, a semiconductor layer forming step of forming the gate insulating layer to cover the gate electrode formed in the gate electrode forming step, and thereafter, forming the oxide semiconductor layer on the gate insulating layer, a source/drain forming step of forming the source and drain electrodes by dry etching on the oxide semiconductor layer formed in the semiconductor layer forming step, with the channel region of the oxide semiconductor layer being exposed, and a surface treatment step of performing a surface treatment on the channel region of the oxide semiconductor layer by supplying ozone thereto.

With this method, after the source and drain electrodes are formed on the oxide semiconductor layer by dry etching, a surface treatment is performed on the channel region of the oxide semiconductor layer by supplying ozone thereto. Therefore, ozone is supplied to the channel region of the oxide semiconductor layer in which a change in the composition has occurred due to a lack of oxygen caused by the dry etching, whereby the lack of oxygen in the oxide semiconductor layer can be improved (terminated). As a result, in the thin film transistor, damage to the oxide semiconductor layer can be reduced or suppressed, and in addition, disadvantages which occur due to the composition change caused by the lack of oxygen, such as an increase in off-current, a decrease in electron mobility, occurrence of hysteresis in transfer characteristics, etc., can be reduced or prevented. Therefore, satisfactory thin film transistor characteristics can be obtained.

The thin film transistor manufactured by the method of the present invention has an advantage that the lack of oxygen in the oxide semiconductor layer can be improved to reduce the damage to the oxide semiconductor layer, whereby satisfactory thin film transistor characteristics can be obtained. Therefore, the thin film transistor of the present invention is applicable to an active matrix substrate including a plurality of pixel electrodes arranged in a matrix, and a plurality of thin film transistors each connected to a corresponding one of the plurality of pixel electrodes.

### Advantages of the Invention

According to the present invention, disadvantages of the oxide semiconductor layer which occur due to the composition change caused by the lack of oxygen can be reduced or prevented, whereby satisfactory thin film transistor characteristics can be obtained.

### BRIEF DESCRIPTION OF THE DRAWINGS

FIG. 1 is a cross-sectional view of a liquid crystal display panel including an active matrix substrate according to an embodiment of the present invention.

FIG. 2 is a plan view of the active matrix substrate of the embodiment of the present invention.

FIG. 3 is an enlarged plan view of a pixel portion and a terminal portion of the active matrix substrate of the embodiment of the present invention.

FIG. 4 is a cross-sectional view of the active matrix substrate taken along line A-A of FIG. 3.

FIG. 5 is a cross-sectional view for describing a process of manufacturing the active matrix substrate.

FIG. 6 is a cross-sectional view for describing a process of manufacturing a counter substrate.

FIG. 7 is a diagram schematically showing an entire configuration of a plasma apparatus according to an embodiment of the present invention.

FIG. 8 is a cross-sectional view showing an entire configuration of a plasma generator in the plasma apparatus of the embodiment of the present invention.

FIG. 9 is a diagram schematically showing the plasma apparatus of the embodiment of the present invention which is supplying oxygen radicals.

FIG. 10 is a cross-sectional view of a conventional active matrix substrate including a TFT including an oxide semiconductor layer.

### DESCRIPTION OF EMBODIMENTS

Embodiments of the present invention will be described in detail hereinafter with reference to the accompanying drawings. Note that the present invention is not intended to be limited to the embodiment described below.

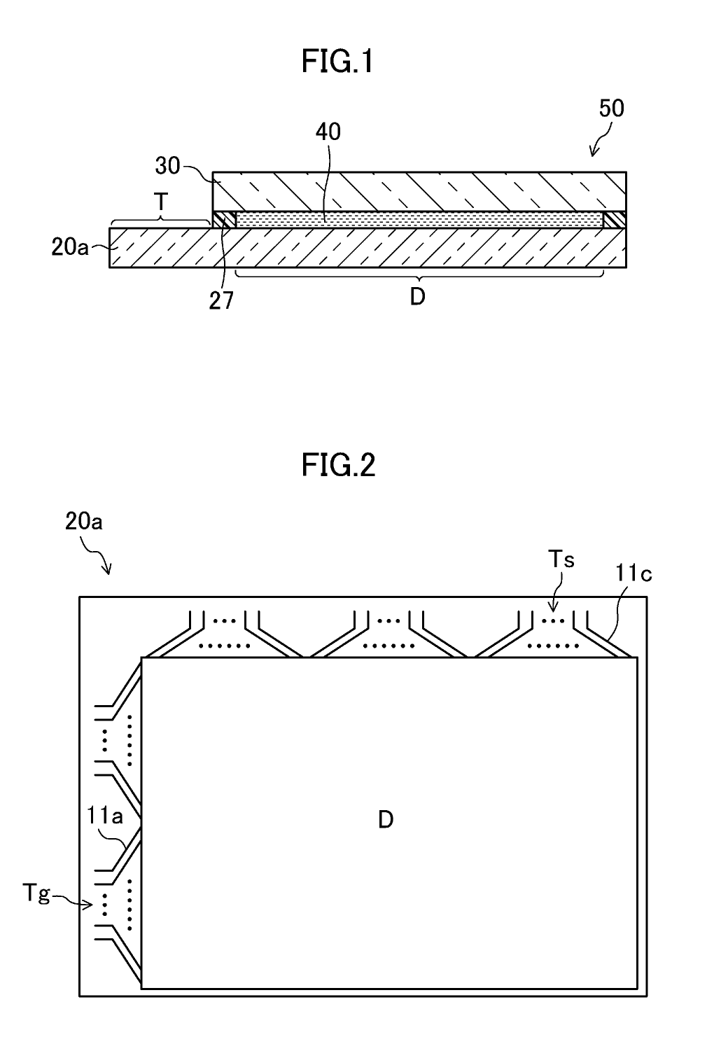

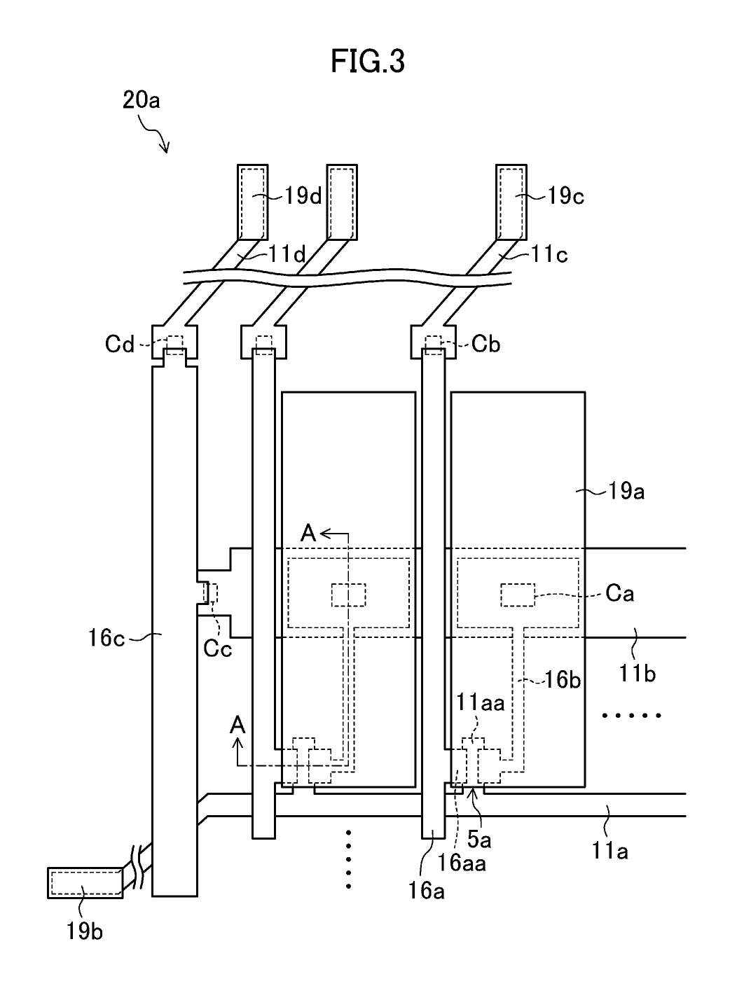

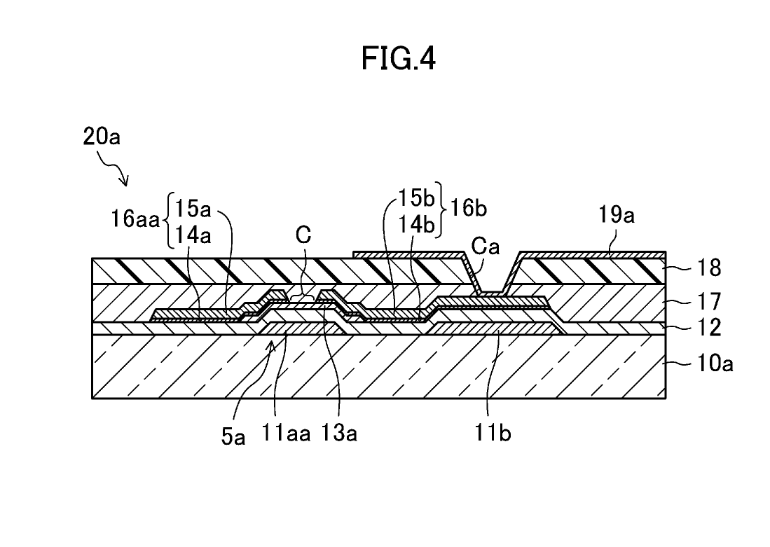

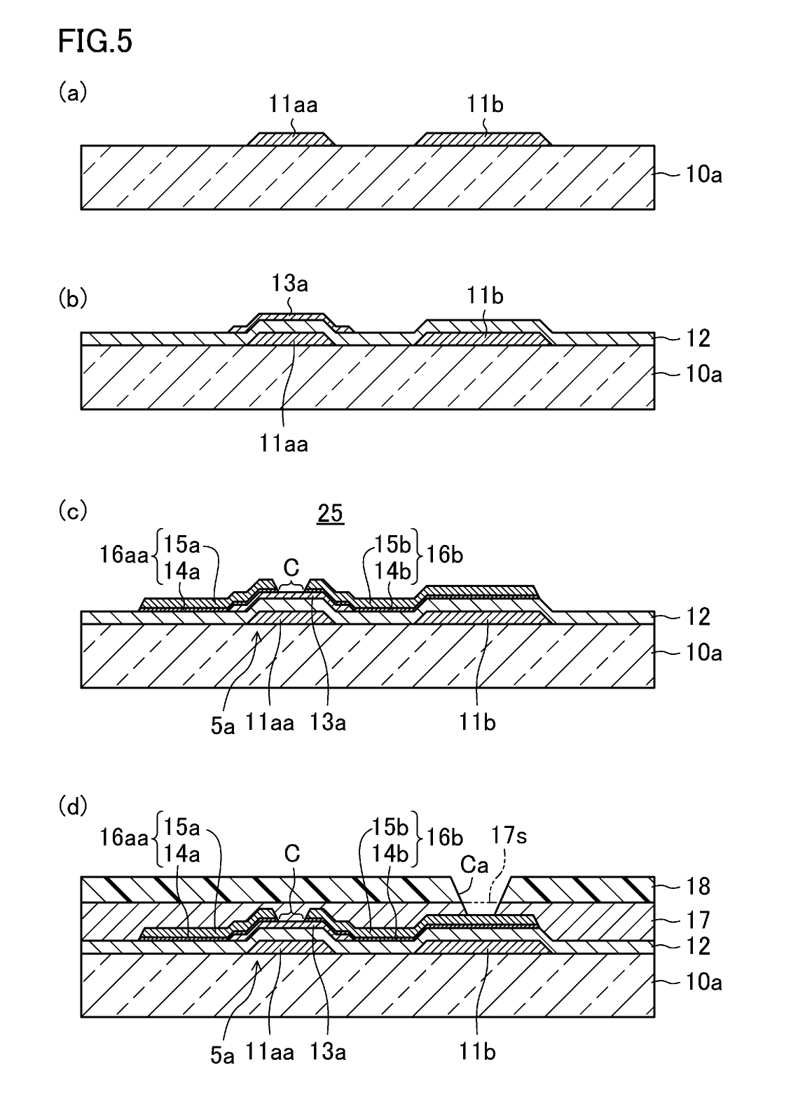

FIG. 1 is a cross-sectional view of a liquid crystal display panel including an active matrix substrate according to an embodiment of the present invention. FIG. 2 is a plan view of the active matrix substrate of the embodiment of the present invention. FIG. 3 is an enlarged plan view of a pixel portion and a terminal portion of the active matrix substrate of the embodiment of the present invention. FIG. 4 is a cross-sectional view of the active matrix substrate taken along line A-A of FIG. 3.

As shown in FIG. 1, the liquid crystal display panel 50 includes an active matrix substrate 20a and a counter substrate 30 which face each other, and a liquid crystal layer 40 which is provided between the active matrix substrate 20a and the counter substrate 30. The liquid crystal display panel 50 also includes a frame-like sealing member 27 which is used to bond the active matrix substrate 20a and the counter substrate 30 together and enclose the liquid crystal layer 40 between the active matrix substrate 20a and the counter substrate 30. As shown in FIG. 1, the liquid crystal display device 50 has a display region D for displaying an image in a portion inside the sealing member 27, and a terminal region T of the active matrix substrate 20a which protrudes from the counter substrate 30.

As shown in FIGS. 2, 3, and 4, the active matrix substrate 20a includes an insulating substrate 10a, a plurality of scanning lines 11a provided on the insulating substrate 10a, extending in parallel to each other in the display region D, a plurality of auxiliary capacitor lines 11b each provided between the corresponding scanning lines 11a, extending in parallel to each other in the display region D, and a plurality of signal lines 16a extending in a direction perpendicular to the scanning lines 11a and in parallel to each other in the display region D. The active matrix substrate 20a also includes a plurality of TFTs 5a at respective corresponding interconnection portions between the scanning lines 11a and the signal lines 16a (i.e., one TFT 5a is provided for each pixel), a protection insulating film 17 covering the TFTs 5a, an interlayer insulating film 18 covering the protection insulating film 17, a plurality of pixel electrodes 19a provided and arranged in a matrix on the interlayer insulating film 18 and connected to the respective corresponding TFTs 5a, and an alignment film (not shown) covering the pixel electrodes 19a.

As shown in FIGS. 2 and 3, the scanning line 11a is extended into a gate terminal region Tg of the terminal region T (see FIG. 1), and is connected to a gate terminal 19b in the gate terminal region Tg.

As shown in FIG. 3, the auxiliary capacitor line 11b is connected via an auxiliary capacitor main line 16c and a relay line 11d to an auxiliary capacitor terminal 19d. Here, the auxiliary capacitor main line 16c is connected to the auxiliary capacitor line 11b via a contact hole Cc formed in a gate insulating layer 12, and to the relay line 11d via a contact hole Cd formed in the gate insulating layer 12.

As shown in FIGS. 2 and 3, the signal line 16a is extended as a relay line 11c into a source terminal region Ts of the terminal region T (see FIG. 1), and is connected to a source terminal 19c in the source the terminal region Ts.

Here, as shown in FIG. 3, the signal line 16a is connected to the relay line 11c via a contact hole Cb formed in the gate insulating layer 12.

As shown in FIGS. 3 and 4, the TFT 5a includes a gate electrode 11aa provided on the insulating substrate 10a, the gate insulating layer 12 covering the gate electrode 11aa, and an island-like oxide semiconductor layer 13a which is provided on the gate insulating layer 12 over the gate electrode 11aa and has a channel region C. The TFT 5a also includes a source electrode 16aa and a drain electrode 16b which are provided on the oxide semiconductor layer 13a, overlapping the gate electrode 11aa and facing each other with the channel region C being interposed between the source electrode 16aa and the drain electrode 16b.

Here, the interlayer insulating film 17 which is provided on the channel region C of the oxide semiconductor layer 13a, covering the source electrode 16aa and the drain electrode 16b (i.e., the TFT 5a), is formed of a spin-on glass material.

As shown in FIG. 3, the gate electrode 11aa is a laterally protruding portion of the scanning line 11a. As shown in FIG. 3, the source electrode 16aa is a laterally protruding portion of the signal line 16a. As shown in FIG. 4, the source electrode 16aa includes a multilayer film of a first conductive layer 14a and a second conductive layer 15a.

As shown in FIGS. 3 and 4, the drain electrode 16b includes a multilayer film of a first conductive layer 14b and a second conductive layer 15b. The drain electrode 16b is connected to the pixel electrode 19a via a contact hole Ca formed in the multilayer film of the interlayer insulating film 17 and the planarization film 18. The drain electrode 16b is also provided over the auxiliary capacitor line 11b with the gate insulating layer 12 being interposed therebetween, thereby forming an auxiliary capacitor.

The oxide semiconductor layer 13a includes, for example, an oxide semiconductor film of indium gallium zinc oxide (IGZO) etc.

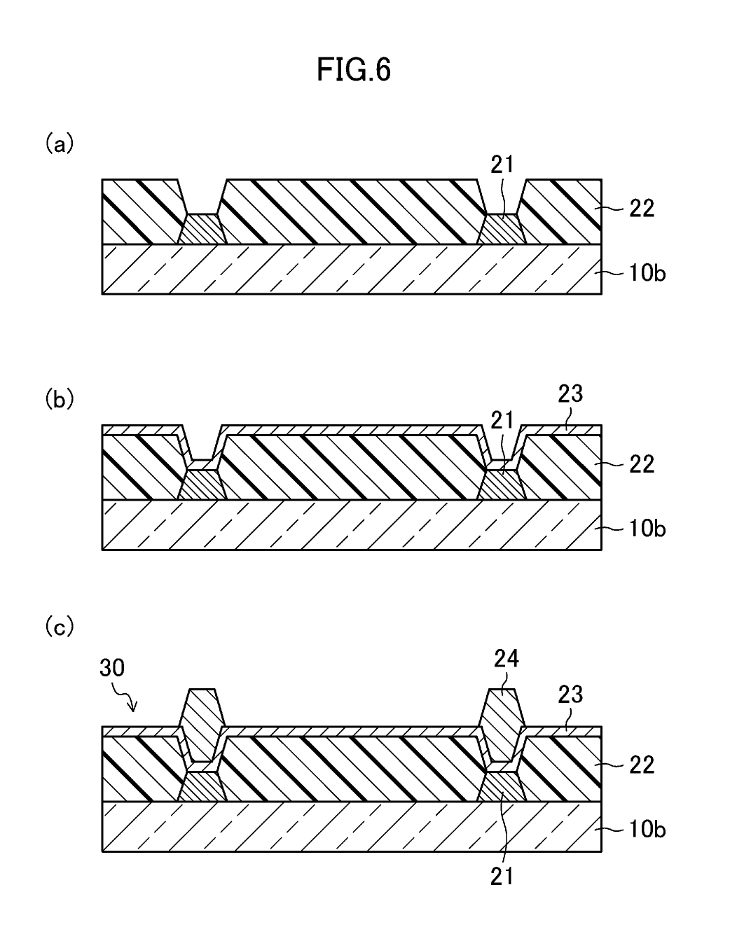

As shown in FIG. 6(c) described below, the counter substrate 30 includes an insulating substrate 10b, a black matrix 21 with a grid pattern provided on the insulating substrate 10b, and a color filter layer including color layers 22 (e.g., a red layer, a green layer, and a blue layer, etc.) which are each provided between grid bars of the black matrix 21. The counter substrate 30 also includes a common electrode 23 covering the color filter layer, a photospacer 24 provided on the common electrode 23, and an alignment film (not shown) covering the common electrode 23.

The liquid crystal layer 40 is formed, for example, of a nematic liquid crystal material having electro-optic properties.

In the liquid crystal display panel 50 thus configured, in each pixel P, when a gate signal is sent from a gate driver (not shown) through the scanning line 11a to the gate electrode 11aa, so that the TFT 5a is turned on, a source signal is sent from a source driver (not shown) through the signal line 16a to the source electrode 16aa, so that predetermined charge is written through the oxide semiconductor layer 13a and the drain electrode 16b to the pixel electrode 19a.

In this case, a potential difference occurs between the pixel electrode 19a of the active matrix substrate 20a and the common electrode 23 of the counter substrate 30, and therefore, a predetermined voltage is applied to the liquid crystal layer 40 (i.e., the liquid crystal capacitor of the pixel) and the auxiliary capacitor connected in parallel to the liquid crystal capacitor.

In the liquid crystal display panel 50, in each pixel P, the alignment of the liquid crystal layer 40 is changed, depending on the magnitude of the voltage applied to the liquid crystal layer 40, to adjust the light transmittance of the liquid crystal layer 40, whereby an image is displayed.

Next, an example method for manufacturing the liquid crystal display panel 50 of this embodiment will be described with reference to FIGS. 5 and 6. FIG. 5 is a cross-sectional view for describing a process of manufacturing the active matrix substrate 20a. FIG. 6 is a cross-sectional view for describing a process of manufacturing the counter substrate 30. Note that the manufacturing method of this embodiment includes an active matrix substrate fabricating process, a counter substrate fabricating process, and a liquid crystal injecting process.

Firstly, the active matrix substrate fabricating process will be described.

<Gate Electrode Forming Step>

Initially, for example, a titanium film (thickness: about 200-500 nm) etc. is formed by sputtering on the entire insulating substrate 10a, such as a glass substrate, etc. Thereafter, photolithography, wet etching, and resist removal and cleaning are performed on the titanium film. As a result, as shown in FIGS. 3 and 5(a), the scanning line 11a, the gate electrode 11aa, the auxiliary capacitor line 11b, and the relay lines 11c and 11d are formed.

In this embodiment, the titanium film having a monolayer structure has been illustrated as a metal film which is included in the gate electrode 11aa. Alternatively, a titanium film (thickness: 30-150 nm), an aluminum film (thickness: 200-500 nm), and a titanium film (thickness: 30-150 nm) may be stacked together, and thereafter, photolithography, wet etching, and resist removal and cleaning may be performed on the multilayer film to form the gate electrode 11aa. Alternatively, the gate electrode 11aa may be formed of copper, molybdenum, or a compound thereof, or a multilayer film of a copper film, a titanium film, etc.

<Semiconductor Layer Forming Step>

Next, for example, a silicon nitride film (thickness: about 200-500 nm) is formed by CVD on the entire substrate on which the scanning line 11a, the gate electrode 11aa, the auxiliary capacitor line 11b, and the relay lines 11c and 11d have been formed, thereby forming the gate insulating layer 12 covering the gate electrode 11aa and the auxiliary capacitor line 11b. Thereafter, for example, an IGZO oxide semiconductor film (thickness: about 5-300 nm) is formed by sputtering, and thereafter, photolithography, wet etching, and resist removal and cleaning are performed on the oxide semiconductor film. As a result, as shown in FIG. 5(b), the oxide semiconductor layer 13a is formed (the semiconductor layer forming step in FIG. 5).

While, in this embodiment, the gate insulating layer 12 having a monolayer structure of a silicon nitride film has been illustrated, the gate insulating layer 12 may have a monolayer structure of a silicon oxide film or a multilayer structure of a silicon oxide film (upper layer) and a silicon nitride film (lower layer), for example.

<Source/Drain Forming Step>

Moreover, for example, a titanium film (thickness: about 30-150 nm) which is a first conductive layer 14a, 14b (lower layer) and a copper film (thickness: about 50-400 nm) which is a second conductive layer 15a, 15b (upper layer), etc. are successively formed by sputtering on the entire substrate on which the oxide semiconductor layer 13a has been formed. Thereafter, photolithography and wet etching are performed on the copper film, and dry etching and resist removal and cleaning are performed on the titanium film. As a result, as shown in FIG. 5(c), the signal line 16a (see FIG. 3), the source electrode 16aa, the drain electrode 16b, and the auxiliary capacitor main line 16c (see FIG. 3) are formed with the channel region C of the oxide semiconductor layer 13a being exposed.

In other words, in this step, the source electrode 16aa and the drain electrode 16b are formed on the oxide semiconductor layer 13a formed in the semiconductor layer forming step, by performing dry etching on the first conductive layer 14a, 14b contacting at least the channel region C of the oxide semiconductor layer 13a, with the channel region C of the oxide semiconductor layer 13a being exposed.

<Surface Treatment Step>

Next, a surface treatment is performed on the substrate 25 (hereinafter referred to as a “target substrate”) on which the source electrode 16aa and the drain electrode 16b of FIG. 5(c) have been formed and the channel region C of the oxide semiconductor layer 13a has been exposed. Specifically, oxygen radicals (O₂⁻) which are produced by an atmospheric-pressure plasma treatment are supplied to the channel region C of the oxide semiconductor layer 13a in which a change in the composition due to a lack of oxygen has occurred due to the dry etching, whereby the lack of oxygen is improved.

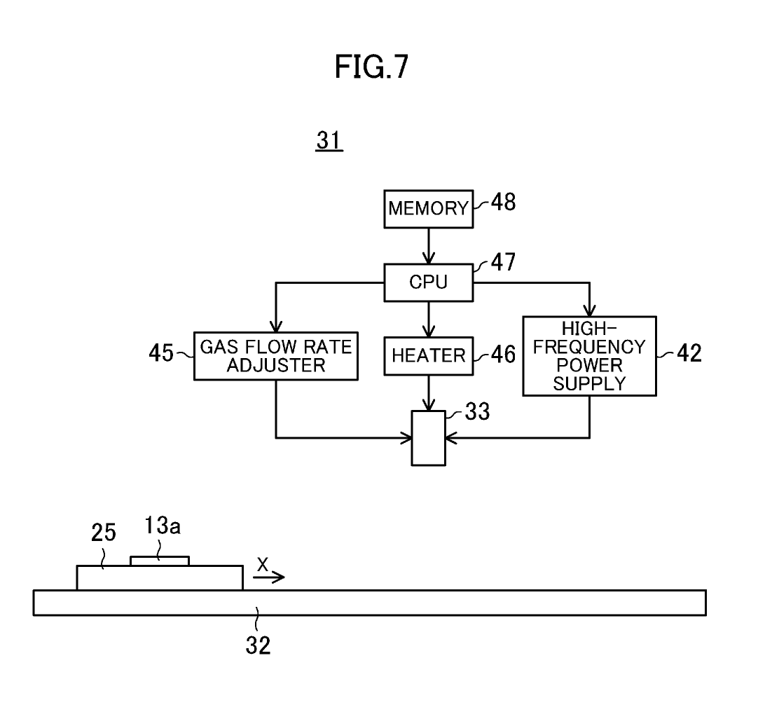

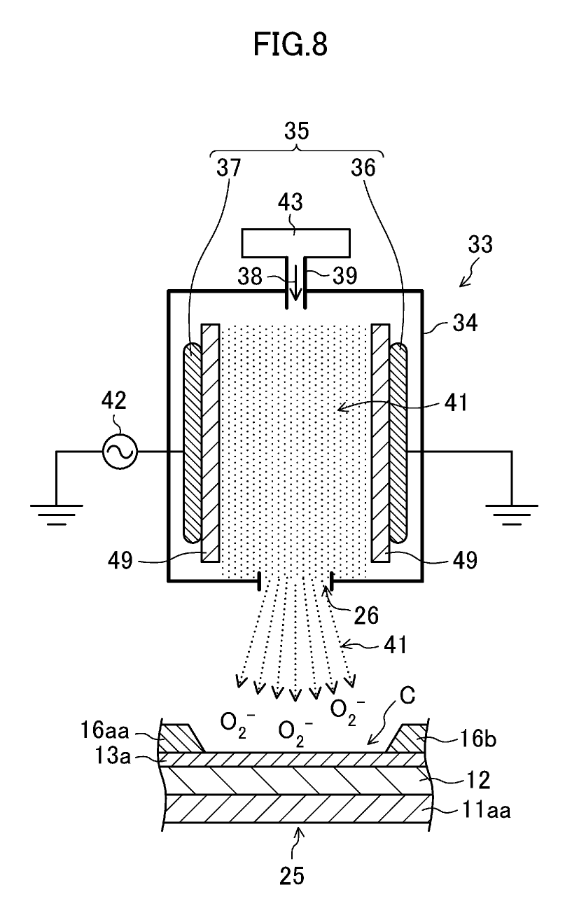

FIG. 7 is a diagram schematically showing an entire configuration of a plasma apparatus according to an embodiment of the present invention. FIG. 8 is a cross-sectional view showing an entire configuration of a plasma generator in the plasma apparatus of the embodiment of the present invention.

As shown in FIG. 7, the plasma apparatus 31 includes a transport conveyor 32 which is a transporter for transporting the target substrate 25, and a plasma generation unit 33 which is a plasma generator which generates plasma to produce oxygen radicals which are to be supplied to a surface of the oxide semiconductor layer 13a of the target substrate 25.

The transport conveyor 32 is, for example, a transport belt. When the target substrate 25 which is a target for the treatment is placed on the transport conveyor 32, the transport conveyor 32 transports the target substrate 25 in a direction indicated by an arrow X in FIG. 7 in a conveyor belt manner.

Note that the transport conveyor 32 is not particularly limited and may be any device that can transport the target substrate 25. Instead of the transport belt, transport rollers may be employed.

As shown in FIG. 8, the plasma generation unit 33 includes a plasma generation chamber 34 and a plasma discharge generator 35 which is provided in the plasma generation chamber 34. As shown in FIG. 8, by supplying oxygen radicals to the surface of the oxide semiconductor layer 13a of the target substrate 25, the lack of oxygen in the oxide semiconductor layer 13a is improved (terminated).

As shown in FIG. 8, the plasma discharge generator 35 includes a pair of plate-like electrodes (i.e., a power supply electrode 37 and a ground electrode 36) facing each other in a lateral direction in the plasma generation chamber 34.

As shown in FIG. 8, a pair of dielectric members 49 (e.g., the members are formed of glass or ceramic) are provided on surfaces of the ground electrode 36 and the power supply electrode 37 facing each other. By interposing the dielectric members 49 between the ground electrode 36 and the power supply electrode 37, discharge can be stably sustained even under atmospheric pressure (dielectric member barrier discharge).

The plasma discharge generator 35 is configured so that a voltage is applied between the ground electrode 36 and the power supply electrode 37 to generate a plasma state of a material gas 41 as a streamer discharge phenomenon of the generated electric field.

As a result, dissociation of the material gas (oxygen gas in this embodiment) 41 is accelerated between the ground electrode 36 and the power supply electrode 37 to produce radicals (oxygen radicals).

In other words, in this embodiment, oxygen radicals are produced by decomposing the material gas 41 by plasma.

Note that, in this embodiment, for example, nitrogen gas is used as carrier gas for the material gas 41.

The oxygen radicals thus produced diffuse into the surface of the oxide semiconductor layer 13a formed on the target substrate 25, to improve the lack of oxygen generated in the surface of the oxide semiconductor layer 13a.

As shown in FIG. 8, the power supply electrode 37 is provided and fixed in the plasma generation chamber 34, and the ground electrode 36 is provided to the right of the power supply electrode 37.

In the plasma generation chamber 34, a gas supply pipe 39 for introducing the material gas 41 is formed between the ground electrode 36 and the power supply electrode 37.

As shown in FIG. 8, a high-frequency power supply 42 which supplies power to the plasma discharge generator 35, and a gas supplier 43 which supplies the material gas 41 to the plasma generation chamber 34, are provided outside the plasma generation chamber 34.

The high-frequency power supply 42 is, for example, configured to generate a high-frequency voltage having a frequency of 50 kHz, etc., and is connected to the power supply electrode 37. On the other hand, the ground electrode 36 is grounded. Note that the high-frequency power supply 42 may be, for example, configured to generate a high-frequency voltage of 10 kHz, 100 kHz, or higher.

The plasma generation unit 33 is, for example, configured to introduce the material gas 41 into the plasma generation chamber 34, where the pressure is about 10-3000 Pa. The material gas 41 is supplied from the gas supplier 43 through the gas supply pipe 39 to a space between the power supply electrode 37 and the ground electrode 36.

The gas supplier 43 includes a gas cylinder, etc., and is connected via the gas supply pipe 39 to the plasma generation chamber 34.

As shown in FIG. 7, the plasma apparatus 31 includes a gas flow rate adjuster 45 which adjusts the flow rate of the material gas 41 supplied from the gas supplier 43, and a heater 46 for maintaining cooling water supplied to the plasma generation chamber 34 at a temperature of about 30° C.

The plasma apparatus 31 also includes a CPU 47 which is a controller for controlling the high-frequency power supply 42, the gas flow rate adjuster 45, and the heater 46, and a memory 48 which is a storage. The high-frequency power supply 42, the gas flow rate adjuster 45, and the heater 46, and the memory 48, are connected to the CPU 47. The CPU 47 is configured to control each unit based on a program stored in the memory 48. Note that the CPU 47 also controls the transport conveyor 32 and the plasma generation unit 33 based on a program stored in the memory 48.

In the plasma apparatus 31, the gas supplier 43 is driven to introduce the material gas 41 into the plasma generation chamber 34, and set the inside of the plasma generation chamber 34 to atmospheric pressure (i.e., ambient gas under a pressure in the vicinity of atmospheric pressure). As indicated by an arrow 38 in FIG. 8, the material gas 41 is introduced from the gas supplier 43 through the gas supply pipe 39 into the plasma generation chamber 34.

Note that the flow rate of the oxygen gas is, for example, 15 cc/min, and the flow rate of the nitrogen gas (carrier gas) is, for example, 1500 cc/min.

By introducing the material gas 41 and driving the high-frequency power supply 42 to apply a high-frequency voltage between the ground electrode 36 and the power supply electrode 37, the plasma state of the oxygen gas (the material gas 41) is generated as a streamer discharge phenomenon.

As a result, dissociation of the material gas (oxygen gas) 41 is accelerated to produce a high density of radicals (oxygen radicals) in the material gas 41.

As shown in FIG. 8, the material gas 41 containing oxygen radicals which have been produced by the plasma generation unit 33 facing the oxide semiconductor layer 13a are ejected by inflation of the gas during discharging and are supplied through an opening 26 formed in the plasma generation chamber 34 to the surface of the oxide semiconductor layer 13a formed on the target substrate 25, whereby the lack of oxygen in the oxide semiconductor layer 13a is improved (terminated).

Next, a method for performing a surface treatment in which oxygen radicals are supplied to the oxide semiconductor layer 13a by the plasma apparatus 31, will be described.

The plasma apparatus 31 is used to perform a plasma treatment on the target substrate 25 under atmospheric pressure as follows. Initially, as shown in FIG. 7, the target substrate 25 on which the oxide semiconductor layer 13a has been formed is transported in a transport direction X by the transport conveyor 32. Note that the target substrate 25 is transported at a constant transport speed (e.g., 30 cm/min).

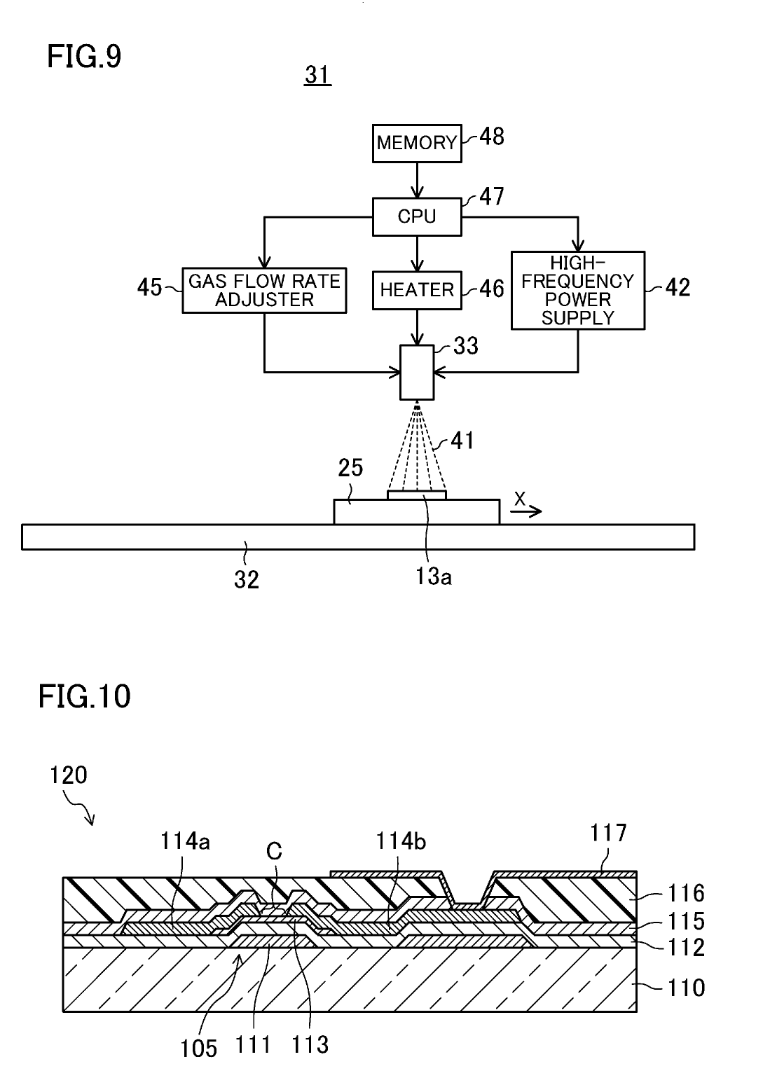

Next, as shown in FIGS. 8 and 9, when the target substrate 25 has been transported to a position where the oxide semiconductor layer 13a and the plasma generation unit 33 face each other, the plasma generation unit 33 generates and supplies the material gas 41 containing oxygen radicals to the oxide semiconductor layer 13a of the transported target substrate 25.

Thus, the material gas 41 containing oxygen radicals is supplied to the surface of the oxide semiconductor layer 13a formed on the target substrate 25, whereby the lack of oxygen in the oxide semiconductor layer 13a is improved (terminated).

Note that the distance between the oxide semiconductor layer 13a and the plasma generation unit 33 when the oxide semiconductor layer 13a and the plasma generation unit 33 face each other as shown in FIGS. 8 and 9 can be changed as appropriate. However, the distance is preferably 1 mm or more and 5 mm or less in order to prevent the oxide semiconductor layer 13a and the plasma generation unit 33 from making contact with each other and thereby reliably supply oxygen radicals to the surface of the oxide semiconductor layer 13a.

<Protection Insulating Layer/Interlayer Insulating Layer Forming Step>

Next, on the entire target substrate 25 to which oxygen radicals have been supplied, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm as shown in FIG. 5(d).

Thereafter, on the entire substrate on which the SOG film 17s has been formed, a photosensitive organic insulating film having a thickness of about 1.0-3.0 μm is applied by spin coating or slit coating, and thereafter, exposure and development are performed on the applied film, to form the interlayer insulating layer 18. Thereafter, dry etching is performed on the SOG film 17s exposed through the interlayer insulating layer 18. As a result, as shown in FIG. 5(d), the protection insulating layer 17 is formed.

<Pixel Electrode Forming Step>

Finally, a transparent conductive film, such as an indium tin oxide (ITO) film (thickness: about 50-200 nm) etc., is formed by sputtering on the entire substrate on which the protection insulating film 17 and the interlayer insulating film 18 have been formed. Thereafter, photolithography, wet etching, and resist removal and cleaning are performed on the transparent conductive film. As a result, as shown in FIGS. 3 and 4, the pixel electrode 19a, the gate terminal 19b, the source terminal 19c, and the auxiliary capacitor terminal 19d are formed.

Thus, the active matrix substrate 20a can be fabricated.

<Counter Substrate Fabricating Process>

Initially, for example, a black-colored photosensitive resin is applied on the entire insulating substrate 10b, such as a glass substrate etc., by spin coating or slit coating, and thereafter, exposure and development are performed on the applied film. As a result, as shown in FIG. 6(a), the black matrix 21 having a thickness of about 1.0 μm is formed.

Next, on the entire substrate on which the black matrix 21 has been formed, a red-, green-, or blue-colored photosensitive resin is applied by spin coating or slit coating, and thereafter, exposure and development are performed on the applied film, thereby forming the color layer 22 with a selected color (e.g., a red color layer) having a thickness of about 2.0 μm as shown in FIG. 6(a). Moreover, by repeating a similar process for the two other colors, the color layers 22 with the two other colors (e.g., a green color layer and a blue color layer) each having a thickness of about 2.0 μm are formed.

Moreover, a transparent conductive film, such as an ITO film etc., is deposited by sputtering on the substrate on which the color layers 22 have been formed. As a result, as shown in FIG. 6(b), the common electrode 23 having a thickness of about 50-200 nm is formed.

Finally, a photosensitive resin is applied by spin coating or split coating on the substrate on which the common electrode 23 has been formed, and thereafter, exposure and development are performed on the applied film. As a result, as shown in FIG. 6(c), the photospacer 24 having a thickness of about 4 nm is formed.

Thus, the counter substrate 30 can be fabricated.

<Liquid Crystal Injecting Process>

Initially, a polyimide resin film is applied by a printing method on each of a surface of the active matrix substrate 20a fabricated in the active matrix substrate fabricating process and a surface of the counter substrate 30 fabricated in the counter substrate fabricating process, and thereafter, baking and rubbing are performed on the applied films, thereby forming alignment films.

Next, a frame-like sealing member, for example, of an ultraviolet (UV) and thermal curing resin is printed on the surface of the counter substrate 30 on which the alignment film has been formed, and thereafter, a liquid crystal material is dropped into a region inside the sealing member.

Moreover, the counter substrate 30 on which the liquid crystal material has been dropped, and the active matrix substrate 20a on which the alignment film has been formed, are joined with each other under reduced pressure. Thereafter, the counter substrate 30 and the active matrix substrate 20a thus joined with each other are exposed to the atmosphere so that pressure is applied on the front and rear surfaces of the two-substrate structure.

Thereafter, the sealing member interposed between the counter substrate 30 and the active matrix substrate 20a joined with each other is irradiated with UV light and then heated, whereby the sealing member is cured.

Finally, the two-substrate structure in which the sealing member has been cured is cut by dicing to remove an unnecessary portion.

Thus, the liquid crystal display device 50 of this embodiment can be manufactured.

According to this embodiment described above, the following advantages can be obtained.

(1) In this embodiment, after the source electrode 16aa and the drain electrode 16b are formed on the oxide semiconductor layer 13a by dry etching, a surface treatment is performed on the channel region C of the oxide semiconductor layer 13a by supplying oxygen radicals thereto. Therefore, by supplying oxygen radicals to the channel region C of the oxide semiconductor layer 13a in which a change in the composition has occurred due to a lack of oxygen caused by dry etching, the lack of oxygen in the oxide semiconductor layer 13a can be improved (terminated). As a result, in the thin film transistor 5a, damage to the oxide semiconductor layer 13a can be reduced or prevented, and in addition, disadvantages which occur due to the composition change caused by the lack of oxygen, such as an increase in off-current, a decrease in electron mobility, occurrence of hysteresis in transfer characteristics, etc., can be reduced or prevented. Therefore, satisfactory thin film transistor characteristics can be obtained.

(2) In this embodiment, in the surface treatment step, oxygen radicals which are produced by the atmospheric-pressure plasma treatment are supplied. Because the atmospheric-pressure plasma treatment is used to produce oxygen radicals, oxygen radicals can be produced by a simple technique. Also, unlike the vacuum plasma treatment, a line gas, such as nitrogen gas etc., can be used, and therefore, inert gas is not required, resulting in a reduction in cost compared to the vacuum plasma treatment.

(3) In this embodiment, oxygen radicals are produced by decomposing oxygen gas by plasma. Therefore, oxygen radicals can be produced by a simple technique.

(4) In this embodiment, oxygen radicals are produced by the plasma generation unit 33 facing the oxide semiconductor layer 13a. Therefore, unlike commonly used vacuum plasma apparatuses, in which a target to be treated is provided between electrodes, the plasma generation unit 33 is positioned to face the oxide semiconductor layer 13a which is a target to be treated, and therefore, only oxygen radicals can be supplied to the channel region C of the oxide semiconductor layer 13a without damage to the oxide semiconductor layer 13a which is caused by the plasma treatment. Therefore, the lack of oxygen in the oxide semiconductor layer 13a can be improved without damage caused by the plasma treatment.

(5) In this embodiment, oxygen radicals are supplied to the channel region C while the oxide semiconductor layer 13a is being transported. Therefore, oxygen radicals can be efficiently supplied to the entire channel region C of the oxide semiconductor layer 13a. As a result, the lack of oxygen in the oxide semiconductor layer 13a can be more effectively improved.

(6) In this embodiment, the oxide semiconductor layer is formed of In—Ga—Zn—O metal oxide. Therefore, the thin film transistor 5a can have satisfactory characteristics, i.e., high mobility and low off-current.

Note that the above embodiment may be modified as follows.

While, in the above embodiment, the oxide semiconductor layer 13 is formed of IGZO, the oxide semiconductor layer 13a is not limited to this. The oxide semiconductor layer 13a may be formed of a metal oxide material containing at least one of indium (In), gallium (Ga), aluminum (Al), silicon (Si), copper (Cu), and zinc (Zn). The oxide semiconductor layer 13a formed of the material can have a high mobility even if the oxide semiconductor layer 13a is amorphous, and therefore, can provide a large on-resistance of the switching element. Therefore, the difference in output voltage during data read operation increases, resulting in an improvement in the S/N ratio. The oxide semiconductor layer 13a may be an oxide semiconductor film, for example, of IZO (In—Zn—O), zinc oxide (Zn—O), etc., in addition to IGZO (In—Ga—Zn—O).

While, in the above embodiment, the plasma generation unit 33 is fixed and the target substrate 25 is transported, the target substrate 25 may be fixed and the plasma generation unit 33 may be transported.

While, in the surface treatment step of the above embodiment, the surface treatment is performed on the channel region C of the oxide semiconductor layer 13a by supplying oxygen radicals thereto, ozone (O₃) may be employed in the surface treatment step instead of oxygen radicals. Specifically, in the source/drain forming step, the source electrode 16aa and the drain electrode 16b may be formed on the oxide semiconductor layer 13a by dry etching, and the channel region C of the oxide semiconductor layer 13a may be exposed, and thereafter, a surface treatment may be performed on the channel region C of the oxide semiconductor layer 13a by supplying ozone thereto.

With such a configuration, as in the case where oxygen radicals are supplied, ozone is supplied to the surface of the oxide semiconductor layer 13a formed on the target substrate 25, whereby the lack of oxygen in the oxide semiconductor layer 13a can be improved (terminated). Therefore, an advantage similar to (1) can be obtained.

### INDUSTRIAL APPLICABILITY

The present invention is useful for a method for manufacturing an active matrix substrate including a semiconductor layer of an oxide semiconductor and the active matrix substrate manufactured by the method, for example.

### DESCRIPTION OF REFERENCE CHARACTERS

5a THIN FILM TRANSISTOR
10a INSULATING SUBSTRATE
11aa GATE ELECTRODE
12 GATE INSULATING LAYER
13a OXIDE SEMICONDUCTOR LAYER
16aa SOURCE ELECTRODE
16b DRAIN ELECTRODE
19a PIXEL ELECTRODE
20a ACTIVE MATRIX SUBSTRATE
25 TARGET SUBSTRATE
30 COUNTER SUBSTRATE
31 PLASMA APPARATUS
33 PLASMA GENERATION UNIT (PLASMA GENERATOR)
41 MATERIAL GAS (OXYGEN GAS)
50 LIQUID CRYSTAL DISPLAY PANEL
C CHANNEL REGION

1. A method for manufacturing a thin film transistor including a gate electrode provided on an insulating substrate, a gate insulating layer covering the gate electrode, an oxide semiconductor layer having a channel region provided on the gate insulating layer over the gate electrode, and a source electrode and a drain electrode provided on the oxide semiconductor layer, overlapping the gate electrode and facing each other with the channel region being interposed the source and drain electrodes, the method comprising:
a gate electrode forming step of forming the gate electrode on the insulating substrate;
a semiconductor layer forming step of forming the gate insulating layer to cover the gate electrode formed in the gate electrode forming step, and thereafter, forming the oxide semiconductor layer on the gate insulating layer;
a source/drain forming step of forming the source and drain electrodes by dry etching on the oxide semiconductor layer formed in the semiconductor layer forming step, with the channel region of the oxide semiconductor layer being exposed; and
a surface treatment step of performing a surface treatment on the channel region of the oxide semiconductor layer by supplying oxygen radicals thereto.

2. The method of claim 1, wherein
in the surface treatment step, the oxygen radicals produced by an atmospheric-pressure plasma treatment are supplied.

3. The method of claim 1, wherein
the oxygen radicals are produced by decomposing oxygen gas by plasma.

4. The method of claim 2, wherein
the oxygen radicals are produced by a plasma generator facing the oxide semiconductor layer.

5. The method of claim 4, wherein
the oxygen radicals are supplied to the channel region while the oxide semiconductor layer is being transported.

6. The method of claim 1, wherein
the oxide semiconductor layer is formed of a metal oxide containing at least one selected from the group consisting of indium (In), gallium (Ga), aluminum (Al), silicon (Si), copper (Cu), and zinc (Zn).

7. The method of claim 6, wherein
the oxide semiconductor layer is formed of an In—Ga—Zn—O metal oxide.

8. A method for manufacturing a thin film transistor including a gate electrode provided on an insulating substrate, a gate insulating layer covering the gate electrode, an oxide semiconductor layer having a channel region provided on the gate insulating layer over the gate electrode, and a source electrode and a drain electrode provided on the oxide semiconductor layer, overlapping the gate electrode and facing each other with the channel region being interposed the source and drain electrodes, the method comprising:
a gate electrode forming step of forming the gate electrode on the insulating substrate;
a semiconductor layer forming step of forming the gate insulating layer to cover the gate electrode formed in the gate electrode forming step, and thereafter, forming the oxide semiconductor layer on the gate insulating layer;
a source/drain forming step of forming the source and drain electrodes by dry etching on the oxide semiconductor layer formed in the semiconductor layer forming step, with the channel region of the oxide semiconductor layer being exposed; and
a surface treatment step of performing a surface treatment on the channel region of the oxide semiconductor layer by supplying ozone thereto.

9. A thin film transistor manufactured by the method of claim 1.

10. An active matrix substrate comprising:
a plurality of pixel electrodes arranged in a matrix; and
a plurality of the thin film transistors of claim 9 each connected to a corresponding one of the plurality of pixel electrodes.
